(19) United States
(12) Patent Application Publication
(10) Pub. No.: US 2014/0109825 A1
(43) Pub. Date: Apr. 24, 2014

(54) EQUIPMENT AND METHOD FOR PRODUCING CRYSTAL BY VERTICAL BOAT METHOD

(71) Applicant: Hitachi Metals, Ltd., Tokyo (JP)

(72) Inventors: Hiroshi SASABE, Hitachi (JP); Nobuyoshi Sato, Hitachi (JP); Masatomo Shibata, Hitachi (JP)

(73) Assignee: Hitachi Metals, Ltd., Tokyo (JP)

(21) Appl. No.: 14/054,922

(22) Filed: Oct. 16, 2013

(30) Foreign Application Priority Data
Oct. 18, 2012 (JP) 2012-230861

(51) Int. Cl. C30B 11/00; C30B 11/02

(52) U.S. Cl. CPC C30B 11/006; C30B 11/003; C30B 11/02
USPC 117/76; 117/223

(57) ABSTRACT

Equipment for crystal growth by a vertical boat method includes a crucible enclosing a raw material, an ampoule encapsulating the crucible, and a crystal growth heater provided around the ampoule to heat the raw material. The raw material is melted into a raw material melt by the crystal growth heater, and a temperature of the raw material melt is controlled such that a crystal grows in the crucible from a bottom toward a top thereof. The crucible encloses GaAs as the raw material and Si as a dopant. The ampoule includes an additional B₂O₃ as an additional raw material at a position separated from the raw material, and a B₂O₃ adding-heater to heat the additional B₂O₃ separately from the raw material. A temperature of the additional B₂O₃ is controlled by the B₂O₃ adding-heater during growth of the crystal such that at least a portion of the additional B₂O₃ is melted and supplied into the crucible.

The present application is based on Japanese patent application No. 2012-230861 filed on Oct. 18, 2012, the entire contents of which are incorporated herein by reference.

### BACKGROUND OF THE INVENTION

1. Field of the Invention

The invention relates to an equipment and a method for growing a Si-doped GaAs single crystal by a vertical boat method.

2. Description of the Related Art

A vertical boat method such as vertical Bridgman method is a crystal growth method in which crystal growth starts from a seed crystal preliminarily placed on a bottom of a crucible, crystallization of a raw material melt held in the crucible gradually proceeds upwardly and eventually the whole raw material melt is crystallized. In the vertical boat method, it is possible to obtain a single crystal with less crystal defects such as dislocations since crystal growth can be carried out under relatively smaller temperature gradient than a pulling method.

There are two general methods for preventing a raw material component from dissociating, decomposing and volatilizing from the raw material melt during the crystal growth. One is a method in which a crucible is placed in a growth furnace chamber (pressure vessel) and a liquid surface of the raw material melt is covered with a liquid-encapsulating agent floating thereon, and another is an ampoule enclosing technique in which the entire crucible is contained in an ampoule having a larger dimension.

### SUMMARY OF THE INVENTION

In growing a Si-doped GaAs single crystal, there is a problem that Si as a dopant raw material is segregated (a Si concentration in the raw material melt increases) as the crystal grows and a Si concentration in a GaAs crystal increases non-uniformly from a seed crystal side to a tail portion of the crystal. The increase in the Si concentration means that an N-type carrier concentration in the crystal also increases. Since the GaAs crystal has a limited range of the carrier concentration depending on the intended purpose, it is necessary to control the carrier concentration to within a specified range.

As a measure against this problem, it may be considered that B₂O₃ capable of gettering Si in the raw material melt could be added during crystal growth to decrease the Si concentration.

In this case, in the former method, it is possible to relatively easily add B₂O₃ into the crucible even during the crystal growth since an upper portion of the crucible is open in the growth furnace chamber (see, e.g., Japanese patent No. 2677859 or Japanese patent No. 4154773).

However, in the latter method, it is difficult to newly add B₂O₃ having ability of gettering into the crucible during the crystal growth since the entire crucible is contained in the ampoule.

It is an object of the invention to provide an equipment and a method for growing a crystal by a vertical boat method that an ampoule enclosing technique is employed for growing a Si-doped GaAs single crystal and B₂O₃ as a material for gettering of Si is added into a crucible at a given timing during crystal growth to allow a Si concentration in the crystal to be controlled and a Si-doped GaAs single crystal with a greater length than a conventional crystal and with a uniform carrier concentration in a longitudinal direction to be grown.
(1) According to one embodiment of the invention, an equipment for crystal growth by a vertical boat method comprises:

a crucible enclosing a raw material;

an ampoule totally encapsulating the crucible; and

a crystal growth heater provided around the ampoule to heat the raw material,

wherein the raw material is melted into a raw material melt by the crystal growth heater and a temperature of the raw material melt is controlled such that a crystal grows in the crucible from a bottom toward a top thereof,

wherein the crucible encloses GaAs as the raw material and Si as a dopant,

wherein the ampoule comprises an additional B₂O₃ as an additional raw material at a position separated from the raw material, and a B₂O₃ adding-heater to heat the additional B₂O₃ separately from the raw material, and

wherein a temperature of the additional B₂O₃ is controlled by the B₂O₃ adding-heater during growth of the crystal such that at least a portion of the additional B₂O₃ is melted and supplied into the crucible.

In the above embodiment (1) of the invention, the following modifications and changes can be made.

(i) The ampoule further comprises an additional B₂O₃ container at an upper portion of the crucible to enclose the additional B₂O₃, and

wherein the additional B₂O₃ container comprises an adding port formed at a bottom thereof through which the additional B₂O₃ is supplied into the crucible.

(ii) The adding port is formed at a position off a central axis of the crucible.

(iii) The adding port is lidded by a lid of another material having a higher melting point than the additional B₂O₃ before the growth of the crystal, and

wherein the lid is melted by the B₂O₃ adding-heater during the growth of the crystal such that the adding port is opened so as to supply the additional B₂O₃ into the crucible.

(iv) The lid has a shape of a plate and is housed in the additional B₂O₃ container so as to lid the adding port.

(v) The lid has a shape of a bottle-stopper to fit to the adding port and is fitted to the adding port so as to lid the adding port.

(vi) The additional B₂O₃ container comprises a bottom having a shape of a funnel.

(vii) The additional B₂O₃ container comprises PBN.

(viii) The adding port has an inner diameter of 0.3 to 1 mm.

(ix) The crystal growth heater is separated from the B₂O₃ adding-heater by a heat insulation material.

(x) The B₂O₃ adding-heater is disposed above the ampoule.

(xi) A heat-transfer material for induction heating is provided around the additional B₂O₃ container.
(2) According to another embodiment of the invention, a method for crystal growth by a vertical boat method comprises:

forming a raw material melt by melting a raw material held in a crucible; and

controlling a temperature of the raw material melt to grow a crystal in the crucible from the bottom toward the top thereof,

wherein GaAs as the raw material and Si as a dopant are held in the crucible, wherein an additional B₂O₃ as an additional raw material is held at a position separated from the raw material before the growth of the crystal, and

wherein a temperature of the additional B₂O₃ is controlled during the growth of the crystal such that at least a portion of the additional B₂O₃ is melted so as to be supplied into the crucible.

### EFFECTS OF THE INVENTION

According to one embodiment of the invention, an equipment and a method for crystal growth by a vertical boat method can be provided that an ampoule enclosing technique is employed for growing a Si-doped GaAs single crystal and B₂O₃ as a material for gettering of Si is added into a crucible at a given timing during crystal growth to allow a Si concentration in the crystal to be controlled and a Si-doped GaAs single crystal with a greater length than a conventional crystal and with a uniform carrier concentration in a longitudinal direction to be grown.

### BRIEF DESCRIPTION OF THE DRAWINGS

Next, the present invention will be explained in more detail in conjunction with appended drawings, wherein:

FIG. 1A is a cross sectional view showing an equipment for crystal growth by a vertical boat method in an embodiment of the present invention and FIG. 1B is a diagram illustrating an example of temperature distribution thereof;

FIG. 2 is a cross sectional view showing an example of a lid;

FIG. 3 is a cross sectional view showing another example of a lid;

FIG. 4 is a cross sectional view showing an example of an additional B₂O₃ container;

FIG. 5 is a cross sectional view showing another example of an additional B₂O₃ container; and

FIG. 6 is a graph showing a carrier concentration change with respect to fraction melt solidified of the crystal.

### DETAILED DESCRIPTION OF THE PREFERRED EMBODIMENTS

A preferred embodiment of the invention will be described below in conjunction with the appended drawings.

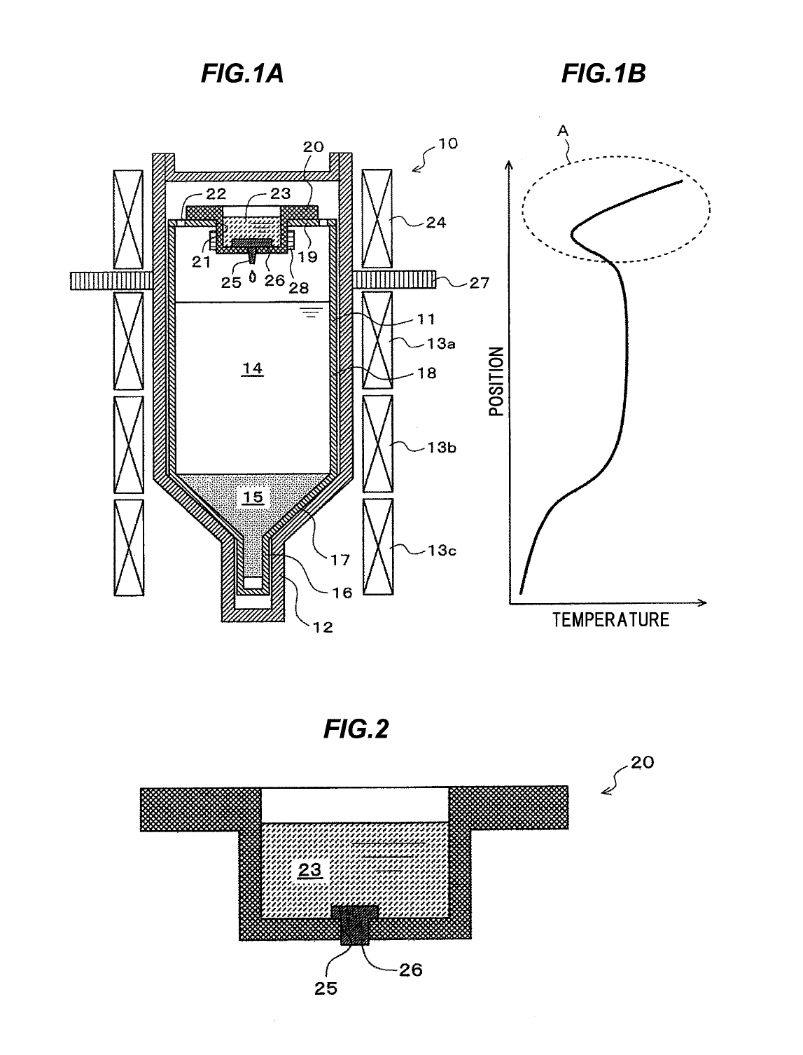

As shown in FIG. 1A, an equipment for crystal growth by a vertical boat method (hereinafter, simply referred to as “crystal growth equipment”) 10 in the present embodiment is provided with a crucible 11 for holding a raw material, an ampoule 12 enclosing the crucible 11 and a crystal growth heater 13 (13a to 13c) provided around the ampoule 12 to heat the raw material, and is configured to melt the raw material by the crystal growth heater 13 to form into a raw material melt 14 and to control temperature of the raw material melt 14 so that a crystal 15 grows in the crucible 11 from the bottom toward the top thereof.

In the present embodiment, a conductive GaAs crystal is grown using GaAs as a crystal raw material and Si as a dopant raw material.

The crucible 11 is formed of quartz glass, etc., and is provided with a cylindrical seed crystal placing portion 16 for placing a crystal seed to be a nucleus of the crystal 15, an diameter enlarging portion 17 in which the crystal 15 is grown with a gradually enlarging outer diameter and a barrel portion 18 in which the crystal 15 is grown with a predetermined outer diameter. In addition to the seed crystal, crystal and dopant raw materials, etc., to be raw materials of the crystal 15 are held in the crucible 11.

An upper portion of the crucible 11 is closed by a crucible lid 19. A mounting hole 21 for mounting a below-described additional B₂O₃ container 20 is formed in the center of the crucible lid 19 and a vent-hole 22 is formed around the periphery of the mounting hole 21 to connect inside of the crucible 11 to inside of the ampoule 12.

The crucible lid 19 serves as a heat shield so that welding heat at the time of enclosing the crucible 11 in the ampoule 12 is not transferred to the inside of a lid 26, and the vent-hole 22 serves to provide an access between atmosphere in the crucible 11 and that in the ampoule 12. The vent-hole 22 may not be provided.

In order to provide temperature gradient such that temperature of the raw material melt 14 in the crucible 11 is gradually getting higher from the bottom toward the top so as to allow the crystal 15 to grow from the bottom toward the top in the crucible 11, the crystal growth heater 13 is composed of plural crystal growth heaters 13a to 13c which can independently control heating temperature.

When using the crystal growth equipment 10 of the present embodiment to grow the crystal 15, in order to prevent Si as a doping material contained in the raw material melt 14 from segregating with growth of the crystal 15 and to preventing a resulting increase in a carrier concentration toward the tail portion of the crystal 15, B₂O₃ capable of gettering Si can be added into the crucible 11 at a given timing during the growth of the crystal 15 to allow characteristics of the crystal 15 to be adjusted at a desired position.

Thus, the crystal growth equipment 10 is provided with an additional B₂O₃ 23 provided in the ampoule 12 at a position separated from the GaAs source and a B₂O₃ adding-heater 24 for applying heat independently from the crystal growth heaters 13a to 13c, and is characterized in controlling temperature of the additional B₂O₃ 23 by the B₂O₃ adding-heater 24 during the growth of the crystal 15 so that at least a portion of the additional B₂O₃ 23 is melted and supplied into the crucible 11.

The crystal growth equipment 10 is further provided with the additional B₂O₃ container 20 which is provided at an upper portion of the crucible 11 in the ampoule 12 to hold the additional B₂O₃ 23. An adding port 25 is formed on a bottom of the additional B₂O₃ container 20 and the additional B₂O₃ 23 is supplied into the crucible 11 through the adding port 25.

Considering viscosity of the additional B₂O₃ 23 and wettability thereof with the additional B₂O₃ container 20, it is desirable that a material of the additional B₂O₃ container 20 be PBN.

Furthermore, the additional B₂O₃ 23 is desirably started to be supplied at an appropriate timing and is then supplied to the raw material melt 14 (GaAs melt) at a constant rate. If a large amount is supplied at a certain timing during crystal growth, a Si concentration (carrier concentration) in a crystal at such a portion is greatly reduced and falls below the acceptable lower limit, causing the carrier concentration in the crystal in a longitudinal direction to be non-uniform. The object of the present application is to stabilize and control the carrier concentration in the crystal in a longitudinal direction to within an acceptable range and is not to simply reduce the carrier concentration. It is possible to adjust the supply rate of the additional B₂O₃ 23 by changing the size of the adding port 25. Based on viscosity of B₂O₃, the appropriate size of the adding port 25 is 0.3 to 1 mm.

Although the additional B₂O₃ 23 which is held in the additional B₂O₃ container 20 can be melted, when needed, by the B₂O₃ adding-heater 24 and supplied into the crucible 11 through the adding port 25, the present embodiment is configured such that the adding port 25 is preliminarily blocked by the lid 26 formed of another material having a higher melting point than the additional B₂O₃ 23 and the lid 26 is melted by the B₂O₃ adding-heater 24 during the growth of the crystal 15 to open the adding port 25 so that the additional B₂O₃ 23 is supplied into the crucible 11.

In this case, the additional B₂O₃ 23 which has a lower melting point than the material of the lid 26 is already substantially completely melted by the time the lid 26 melts. Therefore, it is possible to accurately check viscosity, etc., of the additional B₂O₃ 23 based on temperature and it is easy to control the supply quantity, etc., as compared to the case where the additional B₂O₃ 23 is supplied into the crucible 11 while being melted.

In the present embodiment, GaAs having a higher melting point than B₂O₃ should be used as a material of the lid 26 in order to add B₂O₃. It is because GaAs is also crystal raw material and thus does not have any impact on the growth of the crystal 15 even if supplied with the molten additional B₂O₃ 23 into the crucible 11.

The lid 26 is formed into a plate shape and is housed in the additional B₂O₃ container 20 so as to block the adding port 25. As the lid 26, it is possible to use, e.g., a GaAs substrate formed by slicing a GaAs single crystal ingot.

In the meantime, as shown in FIG. 1B, the upper portion of the crucible 11 is at high temperature in order to maintain a molten state of the raw material melt 14, and temperature of a section A (a portion surrounded by a dashed line) required to control timing of melting the additional B₂O₃ 23 increases along with the temperature of the upper portion of the crucible 11 if the additional B₂O₃ container 20 is placed at a position close to the upper portion of the crucible 11. This causes the lid 26 to be melted at an earlier timing, triggering the supply of the additional B₂O₃ 23 into the crucible 11. Accordingly, the additional B₂O₃ 23 is supplied to the raw material melt 14 in the crucible 11 earlier than a given timing and it makes difficult to control the Si concentration in the crystal 15 to within a specified range.

In order to prevent such a problem, separation distance between a liquid surface of the raw material melt 14 and the additional B₂O₃ container 20 could be increased to greatly differentiate temperature of the raw material melt 14 from the temperature around the additional B₂O₃ container 20. However, this method causes an increase in size of the crystal growth equipment 10.

Therefore, in the crystal growth equipment 10, the crystal growth heater 13 is separated from the B₂O₃ adding-heater 24 by a heat insulation material 27. As a result, heat from the crystal growth heater 13 is less likely to be transferred to the periphery of the additional B₂O₃ container 20 and this allow temperature in a region of the crucible 11 having the raw material melt 14 and temperature of the upper portion (the section A) of the crucible 11 to be independently controlled.

The heat insulation material 27 is formed of a graphite molded material, an alumina material, glass wool or firebricks, etc.

In addition, a heat-transfer material 28 for induction heating is preferably provided around the additional B₂O₃ container 20 so that heat of the B₂O₃ adding-heater 24 is efficiently transferred to the periphery of the additional B₂O₃ container 20.

Next, a method for crystal growth by a vertical boat method in the present embodiment will be described.

The method for crystal growth by a vertical boat method in the present embodiment is a method in which the raw material melt 14 is formed by melting a raw material held in the crucible 11 and temperature of the raw material melt 14 is controlled so that the crystal 15 grows in the crucible 11 from the bottom toward the top thereof, and the method is characterized in that GaAs as the raw material and Si as a dopant are held in the crucible 11, the additional B₂O₃ 23 as an additional raw material is held at a position separated from the raw material and temperature of the additional B₂O₃ 23 is controlled during the growth of the crystal 15 so that at least a portion of the additional B₂O₃ 23 is melted and supplied into the crucible 11.

For growing the crystal 15 using the crystal growth equipment 10 shown in FIG. 1A, a raw material is melted by the crystal growth heater 13 to be formed into the raw material melt 14 and the temperature of the raw material melt 14 is lowered while keeping the temperature of the lower portion of the crucible 11 to be lower than that of the upper portion. Then, in the crucible 11, contact of the raw material melt 14 with a seed crystal placed on the seed crystal placing portion 16 initiates growth of the crystal 15, the raw material melt 14 is gradually crystallized from the bottom toward the top in the crucible 11 and the crystal 15 thereby keeps growing.

The concentration of Si contained as a doping material in the raw material melt 14 increases with the growth of the crystal 15. In order to offset this, the temperature around the additional B₂O₃ container 20 is controlled by the B₂O₃ adding-heater 24 at a given timing to melt the additional B₂O₃ 23 as well as to fuse the lid 26 formed of GaAs so that the additional B₂O₃ 23 which is thus supplied into the crucible 11 getters Si in the raw material melt 14. This prevents the Si concentration in the raw material melt 14 from increasing, and carrier concentration distribution which is uniform in a longitudinal direction is thus obtained. In the crystal 15 grown from the raw material melt 14 with the optimized Si concentration, a carrier concentration in a longitudinal direction thereof is controlled to within a specified range.

As a result, it is possible to control a carrier concentration increase which is caused by segregation of a specific raw material, Si, in the raw material melt 14 along with the growth of the crystal 15 and it is thus possible to obtain acceptable characteristics throughout the longitudinal direction of the crystal 15.

In the crystal growth by a conventional growth equipment, the crystal 15 with acceptable characteristics has a limited length due to a carrier concentration increase caused by segregation. In contrast, use of the crystal growth equipment 10 of the invention allows a carrier concentration increase caused by segregation of the doping material in the raw material melt to be controlled and it is thus possible to growth the crystal 15 which has acceptable characteristics and is longer than a conventional crystal.

Note that, in the crystal growth equipment 10, it is possible to grow not only a conductive GaAs crystal but also other group III-V compound semiconductor crystals, etc. It is possible to grow, e.g., compound semiconductor crystals such as InP, InAs, GaSb and InSb.

In addition, the invention is not intended to be limited to the above-mentioned embodiment, and various changes can be made without departing from the gist of the invention.

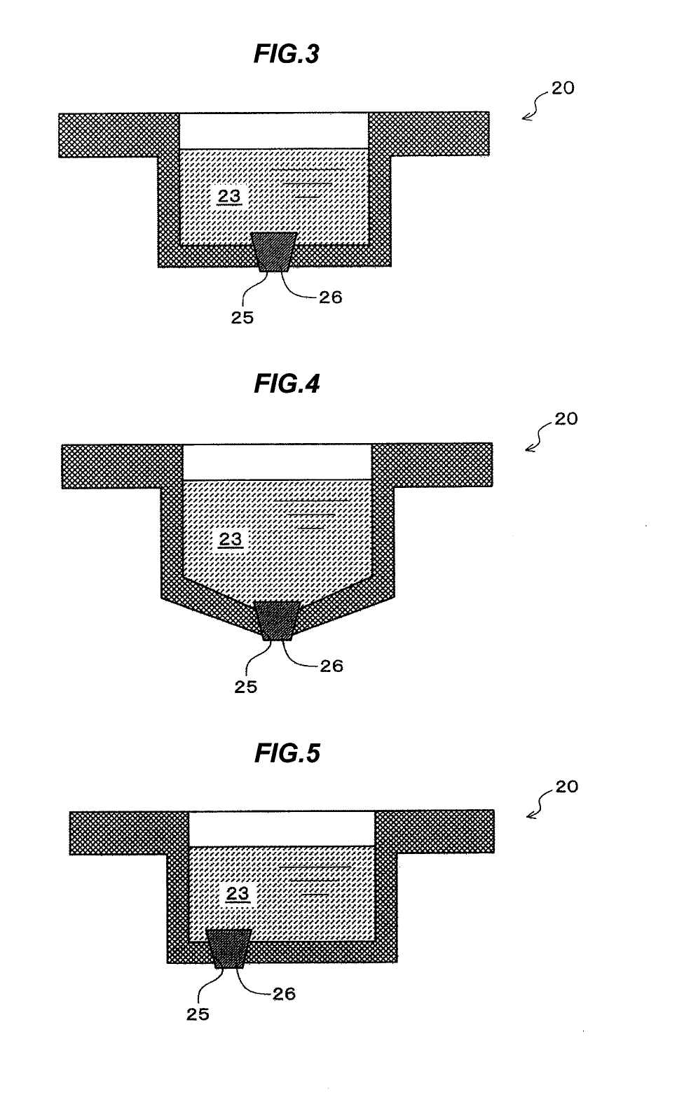

Although, in the present embodiment, the lid 26 is formed into a plate shape and is housed in the additional B₂O₃ container 20 so as to block the adding port 25, the lid 26 may be formed in a bottle-stopper shape fitting to and blocking the adding port 25 as shown in FIG. 2 or may be formed in a circular truncated cone shape as shown in FIG. 3 when it is difficult to form the lid 26 in a bottle-stopper shape.

As such, the lid 26 may have an arbitrary shape as long as the following three conditions are satisfied: the lid 26 is melted at a given timing, the molten additional B₂O₃ 23 does not leak through the lid 26 and the lid 26 does not float on the molten additional B₂O₃ 23.

The bottom of the additional B₂O₃ container 20 may be formed in a funnel shape as shown in FIG. 4 even though it is not specifically mentioned in the present embodiment. Since this shape guides the molten additional B₂O₃ 23 to the adding port 25, the entire additional B₂O₃ 23 can be smoothly and surely supplied into the crucible 11 even when the amount of the additional B₂O₃ 23 is getting low and it is thus possible to use the additional B₂O₃ 23 without any waste. In other words, it is possible to accurately know the maximum supply quantity of the additional B₂O₃ 23.

Furthermore, the adding port 25 is preferably formed at a position shifted from a central axis of the crucible 11, as shown in FIG. 5. It is because, in case that the adding port 25 is shifted from the central axis of the crucible 11, the additional B₂O₃ 23 is added not to the center of the raw material melt 14 but to the vicinity of the sidewall of the crucible 11 when viewing the cross section of the crucible 11 from the top and a stirring effect of the raw material melt 14 when the additional B₂O₃ 23 is supplied can be enhanced.

In addition, although the present embodiment is configured such that the heat-transfer material 28 for induction heating is provided around the additional B₂O₃ container 20 (i.e. at an upper part of the ampoule 12) so that heat of the B₂O₃ adding-heater 24 is efficiently transferred to the periphery of the additional B₂O₃ container 20, other configurations are also acceptable as long as the same effect is obtained.

For example, the B₂O₃ adding-heater 24 may be disposed above (or directly above) the ampoule 12, or lamp heating may be carried out aiming to heat only the additional B₂O₃ 23 or the lid 26 or a concave mirror may be used for light concentrating heating.

### EXAMPLE 1

A 3-inch Si-doped GaAs crystal was grown using the crystal growth equipment 10 shown in FIG. 1A and the lid 26 shown in FIG. 2. 6100 g of GaAs source and 1.2 g of Si dopant were prepared. After the crucible 11 into which GaAs and Si were supplied was tightly sealed in the ampoule 12, the GaAs source and the Si dopant were melted by the crystal growth heater 13 to be formed into the raw material melt 14 and temperature of the raw material melt 14 was controlled, thereby growing the crystal 15 in the crucible 11 from the bottom toward the top thereof. 200 g of the additional B₂O₃ 23 preliminarily held in the additional B₂O₃ container 20 was heated together with the lid 26 by the B₂O₃ adding-heater 24, the adding port 25 was then opened by the melting of the lid 26 at the timing when growth of the GaAs crystal reached the fraction melt solidified of 35%, which started supplying the additional B₂O₃ 23 to the raw material melt 14 in the crucible 11, and 200 g of the additional B₂O₃ 23 was all supplied to the raw material melt 14 at a constant rate by the time the growth of the GaAs crystal reached the fraction melt solidified of 70%.

### Comparative Example 1

A crystal as Comparative Example 1 was grown based on the configuration of Example 1 without mechanism of supplying the additional B₂O₃, i.e., without mechanisms of 19 to 28 in the crystal growth equipment shown in FIG. 1A as the embodiment of the invention. The crystal was grown under the same conditions as Example 1 except that the mechanism of supplying the additional B₂O₃ was not provided.

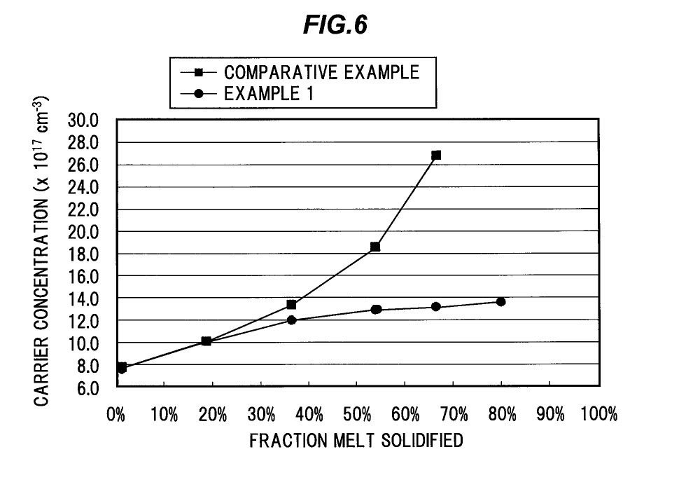

FIG. 6 shows results of carrier concentration with respect to fraction melt solidified of the GaAs crystal in Example 1 and Comparative Example 1. It is understood that the carrier concentration in the crystal grown as Comparative Example 1 significantly increases from around the time where the fraction melt solidified exceeds 35%. On the other hand, in Example 1, an increase in the carrier concentration is suppressed from the timing when B₂O₃ is added and carrier concentration distribution is uniform, as compared to Comparative Example 1.

Note that, regarding the weight of the additional B₂O₃ and the timing to start supplying the additional B₂O₃ in Example 1, a sample was preliminarily taken from a crystal which was grown without supplying the additional B₂O₃, a correlation between the fraction melt solidified of the crystal and the carrier concentration was then examined based on the growth process of the sample, and the supply conditions of the additional B₂O₃ were determined so that a target carrier concentration is obtained. As such, by referring to the preliminary obtained results of growth by a conventional method, the weight of the additional B₂O₃, the supply timing and the size of the adding port 25, etc., are determined so that a target carrier concentration is obtained.

### EXAMPLE 2

A 4-inch Si-doped GaAs crystal was grown using the crystal growth equipment 10 shown in FIG. 1A and the lid 26 shown in FIG. 2. 10000 g of GaAs source, 1.9 g of Si dopant and 320 g of additional B₂O₃ were prepared. The preliminary conducted sample crystal growth has revealed that the carrier concentration in the case of no additional B₂O₃ changes in the same way as the 3-inch crystal in Comparative Example. On the other hand, when B₂O₃ was added during the growth in a region in which the fraction melt solidified of the GaAs crystal is 35 to 70%, the carrier concentration did not significantly increase and uniform carrier concentration distribution was obtained in the same manner as Example 1.

In sum, according to the invention, use of the ampoule enclosing technique and addition of another raw material into a crucible at a given timing during crystal growth allow the carrier concentration to be controlled and also a Si-doped GaAs single crystal with a greater length than a conventional crystal and with a uniform carrier concentration in a longitudinal direction to be grown.

What is claimed is:

1. An equipment for crystal growth by a vertical boat method, comprising:
a crucible enclosing a raw material;
an ampoule encapsulating the crucible; and
a crystal growth heater provided around the ampoule to heat the raw material,
wherein the raw material is melted into a raw material melt by the crystal growth heater and a temperature of the raw material melt is controlled such that a crystal grows in the crucible from a bottom toward a top thereof,
wherein the crucible encloses GaAs as the raw material and Si as a dopant,
wherein the ampoule comprises an additional B₂O₃ as an additional raw material at a position separated from the raw material, and a B₂O₃ adding-heater to heat the additional B₂O₃ separately from the raw material, and
wherein a temperature of the additional B₂O₃ is controlled by the B₂O₃ adding-heater during growth of the crystal such that at least a portion of the additional B₂O₃ is melted and supplied into the crucible.

2. The equipment according to claim 1, wherein the ampoule further comprises an additional B₂O₃ container at an upper portion of the crucible to enclose the additional B₂O₃, and
wherein the additional B₂O₃ container comprises an adding port formed at a bottom thereof through which the additional B₂O₃ is supplied into the crucible.

3. The equipment according to claim 2, wherein the adding port is formed at a position off a central axis of the crucible.

4. The equipment according to claim 2, wherein the adding port is lidded by a lid of another material having a higher melting point than the additional B₂O₃ before the growth of the crystal, and
wherein the lid is melted by the B₂O₃ adding-heater during the growth of the crystal such that the adding port is opened so as to supply the additional B₂O₃ into the crucible.

5. The equipment according to claim 4, wherein the lid has a shape of a plate and is housed in the additional B₂O₃ container so as to lid the adding port.

6. The equipment according to claim 4, wherein the lid has a shape of a bottle-stopper to fit to the adding port and is fitted to the adding port so as to lid the adding port.

7. The equipment according to claim 2, wherein the additional B₂O₃ container comprises a bottom having a shape of a funnel.

8. The equipment according to claim 2, wherein the additional B₂O₃ container comprises PBN.

9. The equipment according to claim 2, wherein the adding port has an inner diameter of 0.3 to 1 mm.

10. The equipment according to claim 1, wherein the crystal growth heater is separated from the B₂O₃ adding-heater by a heat insulation material.

11. The equipment according to claim 1, wherein the B₂O₃ adding-heater is disposed above the ampoule.

12. The equipment according to claim 2, wherein a heat-transfer material for induction heating is provided around the additional B₂O₃ container.

13. A method for crystal growth by a vertical boat method, comprising:
forming a raw material melt by melting a raw material held in a crucible; and
controlling a temperature of the raw material melt to grow a crystal in the crucible from the bottom toward the top thereof,
wherein GaAs as the raw material and Si as a dopant are held in the crucible,
wherein an additional B₂O₃ as an additional raw material is held at a position separated from the raw material before the growth of the crystal, and
wherein a temperature of the additional B₂O₃ is controlled during the growth of the crystal such that at least a portion of the additional B₂O₃ is melted so as to be supplied into the crucible.
